(19) United States
(12) Patent Application Publication
(10) Pub. No.: US 2015/0228607 A1
(43) Pub. Date: Aug. 13, 2015

(54) LAYER STACKS AND INTEGRATED CIRCUIT ARRANGEMENTS

(71) Applicant: Infineon Technologies AG, Neubiberg (DE)

(72) Inventors: Tobias Schmidt, Regensburg (DE); Evelyn Napetschnig, Diex (AT); Franz Stueckler, St. Stefan (AT); Anton Pugatschow, Villach (AT); Mark Harrison, Wernberg (DE)

(21) Appl. No.: 14/692,815

(22) Filed: Apr. 22, 2015

Related U.S. Application Data
(63) Continuation of application No. 12/883,362, filed on Sep. 16, 2010.

(51) Int. Cl. H01L 23/00

(52) U.S. Cl. CPC H01L 24/32; H01L 2224/32227; H01L 2224/29082; H01L 2924/01074; H01L 2924/01073; H01L 2924/01042; H01L 2924/01024; H01L 2924/01023; H01L 2924/01022; H01L 2924/01079; H01L 2924/01047; H01L 2924/01013; H01L 2924/01072; H01L 2924/0104; H01L 2924/01041; H01L 2924/0105; H01L 2924/14; H01L 2924/014; H01L 2924/01322

(57) ABSTRACT

In various embodiments, a layer stack is provided. The layer stack may include a carrier; a first metal disposed over the carrier; a second metal disposed over the first metal; and a solder material disposed above the second metal or a material that provides contact to a solder that is supplied by an external source. The second metal may have a melting temperature of at least 1800° C. and is not or substantially not dissolved in the solder material at least one of during a soldering process and after the soldering process.

### RELATED APPLICATION(S)

The present application is a continuation of U.S. patent application Ser. No. 12/883,362, filed Sep. 16, 2010, the contents of which are incorporated herein by reference in its entirety for all purposes.

### TECHNICAL FIELD

Various embodiments relate generally to layer stacks and integrated circuit arrangements.

### BACKGROUND

In a conventional soldering system including a metallization layer stack (e.g. back side metallization made of aluminum (Al)/titanium (Ti)/nickel (Ni) vanadium (V)/silver (Ag)) and a solder system (e.g. eutectic silver-tin (AgSn)), the exposure of this system to high humidity and high temperature (e.g. H3TRB-method) after having applied a soldering process may result in voids and corrosion, that causes delamination of this system. This may be due to the following: In case that during the soldering process or in a subsequent process, the Ag layer and the NiV layer dissolves in the eutectic solder material, (e.g. at the interface between the Ti layer and the eutectic Sn and Ag rich phase a TiₓSn_{y}[Me]_{z} (Me=metal) phase is formed. At this intermetallic phase the material system may delaminate).

This situation has conventionally been tried to be avoided by increasing the NiV layer thickness (e.g. Al/Ti/NiV/Ag backside metallization). This prolongates the complete consumption of the NiV layer by eutectic solder (e.g. main components are Sn and Ag). The formation of an intermetallic TiₓSn_{y}[Me]_{z} phase that may cause delamination may be avoided, since the eutectic Sn rich solder may no longer come into direct physical contact with the Ti of the Ti layer.

However, the increase of the layer thickness of the NiV layer makes high demands to the deposition process for depositing the NiV layer and to the subsequent processes. The increased deposition time and process temperature may not only result in increased machine holding time and material costs, but they may also create higher mechanical stress and a wafer warpage. The further processing of the wafer will then be made difficult and may even become impossible.

The soldering results in accordance with the increased layer thickness of the NiV layer usually show voids and are generally unsatisfactory.

### SUMMARY

In various embodiments, a layer stack is provided. The layer stack may include a carrier; a first metal disposed over the carrier; a second metal disposed over the first metal; and a solder material disposed above the second metal, or a material that provides contact to a solder material that is supplied by an external source. The second metal may have a melting temperature of at least 1800° C. and is not or substantially not dissolved in the solder material at least one of during a soldering process and after the soldering process. When there is no solder material over the second material, than the solder material may be deployed later in the process by an external source in accordance with various embodiments.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a layer stack in accordance with an embodiment;

FIG. 2 shows a layer stack in accordance with an embodiment; and

FIG. 3 shows an integrated circuit arrangement in accordance with an embodiment.

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

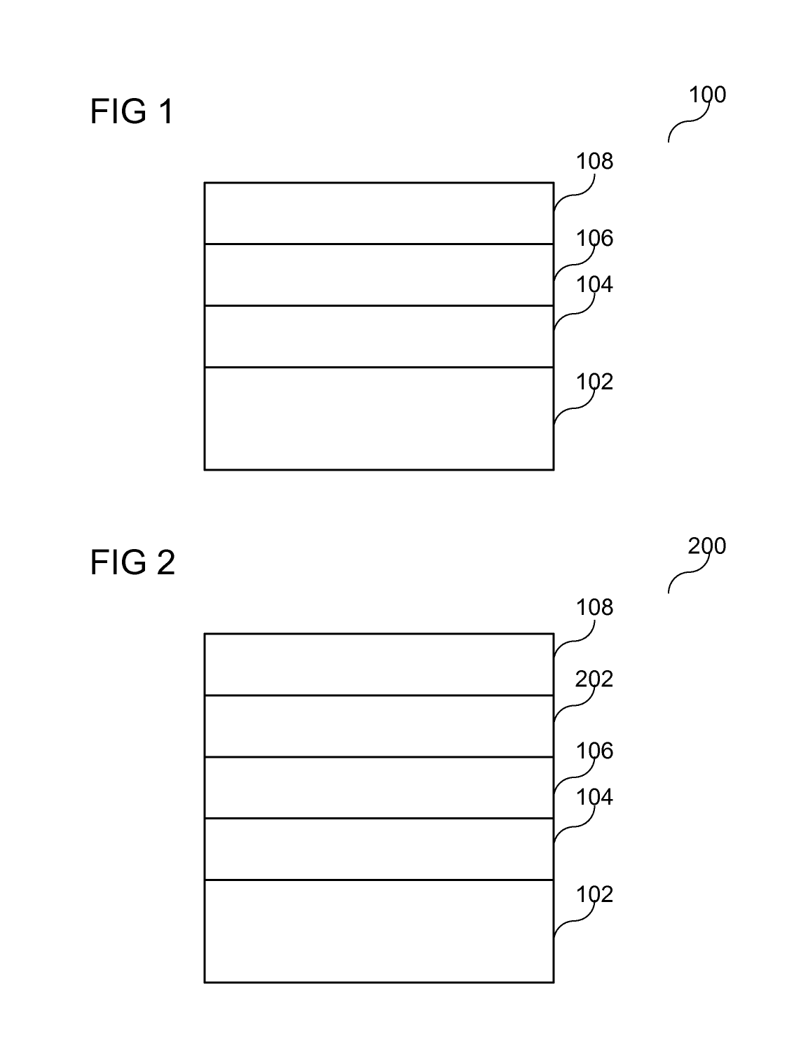

FIG. 1 shows a layer stack 100 in accordance with an embodiment.

As shown in FIG. 1, the layer stack 100 may include a carrier 102.

In various embodiments, the carrier may be a substrate 102. In various embodiments, the substrate (e.g. a wafer substrate) 102 may be made of semiconductor materials of various types, e.g. silicon, germanium, designed materials or other types of material, including polymers, for example, although in other embodiments, other suitable materials may also be used. In various embodiments, the substrate 102 may be made of or may include silicon (doped or undoped), in alternative embodiments, the substrate 102 may be a substrate of a silicon on insulator (SOI) wafer. As an alternative, any other suitable semiconductor materials can be used for the substrate 102, for example semiconductor compound material such as gallium arsenide (GaAs), indium phosphide (InP), but also any suitable ternary semiconductor compound material material such as indium gallium arsenide (InGaAs) or quaternary semiconductor compound material.

In various embodiments, the layer stack 100 may further include at least one electronic component in or on the carrier 102 (not shown in FIG. 1).

Furthermore, in various embodiments, a first metal 104 may be disposed over the carrier 102. In various embodiments, the first metal 104 may be provided as an adhesion layer which in addition provides for an electrical contact to the carrier 102, e.g. to a contact structure provided on or in the carrier 102 (e.g. to one or more contact pads or a metallization, e.g. a back side metallization (which may also be referred to as rear side metallization). In various embodiments, the first metal 104 may include a metal such as e.g. aluminum (Al), titanium (Ti), and/or an alloy with Al and Ti as main constituents. In various embodiments, the first metal 104 may include a double layer structure including a first layer of e.g. Al and a second layer of e.g. Ti. In alternative embodiments, any other suitable metal may be provided for the first metal 104. In various embodiments, the first metal 104 may have a combined layer thickness in the range from about 100 nm to about 2000 nm, e.g. a layer thickness in the range from about 100 nm to about 400 nm e.g. in the case that one metal is used (e.g. Al or Ti), e.g. two metals in the range from about 400 nm for the first layer (e.g. Al) and 200 nm for the second layer (e.g. Ti).

Furthermore, in various embodiments, a second metal 106 may be disposed over the first metal 104. In various embodiments, the second metal 106 may include a metal such as e.g. tungsten (W), tantalum (Ta), nickel (Ni), iron (Fe), palladium (Pd), cobalt (Co), molybdenum (Mo), manganese (Mn), chromium (Cr), copper (Cu), niobium (Nb), and/or vanadium (V). In various embodiments, the second metal 106 may include a first metal component and a second metal component. The first metal component may include a metal such as e.g. tungsten (W), tantalum (Ta), molybdenum (Mo), chromium (Cr), niobium (Nb), and/or hafnium (Hf). In various embodiments, the second metal component may include a metal such as e.g. titanium (Ti), zirconium (Zr), and/or vanadium (V). In alternative embodiments, any other suitable metal or metals may be provided for the second metal 106. In various embodiments, the second metal 106 may have a melting temperature of at least 1800° C. (e.g. a melting temperature of at least about 1800° C. without an upper limit, e.g. a melting temperature in the range from 1800° C. to about 3400° C.) and the second metal 106 is substantially used to be consumed and/or not consumed by the solder and may be an adhesive layer to the solder. In various embodiments, the second metal 106 may have a layer thickness in the range from about 50 nm to about 2000 nm, e.g. a WTi layer thickness in the range from about 50 nm to about 300 nm, e.g. a NiV layer thickness in the range from about 50 nm to about 1000 nm.

Illustratively, in various embodiments, the second metal 106 may be a high melting point material which has a very low solubility or no solubility for the solder and is not/or fractional dissolved in the solder material. Thus, the second metal 106 provides a stable and reliable electrical and mechanical contact between the solder material and the metal of the first metal 104. Furthermore, in various embodiments, the second metal 106 may be configured such that it does not dissolve or only partially dissolve within the solder material during or after a soldering process. In various embodiments, the second metal 106 serves as a solder stop layer, since it does not chemically react with the solder material during the soldering process.

Furthermore, in various embodiments, the layer stack 100 may further include solder material 108 disposed above the second metal 106. In various embodiments, the solder material 108 may include a material such as e.g. tin (Sn); silver (Ag); gold (Au); and/or in binary alloys e.g. AgSn; or AuSn. In various embodiments, in which the layer stack 100 does not include a soldering layer before the soldering process is carried out, the solder material 108 may e.g. include sputtered AuSn, which may be directly sputtered onto e.g. the second metal 106 before the soldering process and/or the solder and/or protective material 108 which may include a protection layer to prevent oxidation or any chemical process with the second metal; e.g. a silver (Ag) layer; gold (Au) or palladium (Pd).

Various embodiments may provide a layer stack which may avoid or at least reduce the formation of voids or cracks and the problem of delamination of the solder material 108.

FIG. 2 shows a layer stack 200 in accordance with an embodiment.

The layer stack 200 shown in FIG. 2 is similar to the layer stack 100 as shown in FIG. 1 and may further include an adhesion conditioning layer 202 configured to increase the adhesion of the solder material 108 (or in alternative embodiments of a soldering layer) with the second metal layer 106. In various embodiments, the adhesion conditioning layer 202 may be disposed over the second metal layer 106. Furthermore, in various embodiments, the solder and/or protective material 108 may be disposed over the adhesion conditioning layer 202. In various embodiments, the adhesion conditioning layer 202 may include nickel-vanadium (NiV), titanium (Ti), tantalum (Ta), copper (Cu) and the nitrides that can be formed with these metals. In various embodiments, the adhesion conditioning layer 202 may have a layer thickness in the range from about 10 nm to about 1000 nm, e.g. a TiN layer thickness in the range from about 10 nm to about 20 nm, e.g. a NiV layer thickness in the range from about 100 nm to about 300 nm.

Some or all of the above described materials and/or layers may be deposited, e.g. by means of a vapor deposition process such as e.g. by means of a chemical vapor deposition process (CVD, e.g. plasma enhanced (PE) CVD) and/or by means of a physical vapor deposition process (PVD, e.g. sputtering). Other suitable deposition process may be provided for depositing the respective materials, depending on the concrete material and possibly the process environment.

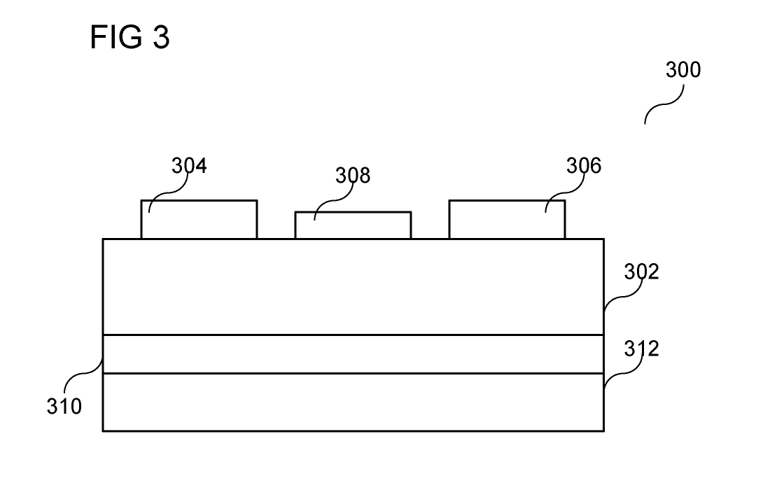

FIG. 3 shows an integrated circuit arrangement 300 in accordance with an embodiment. In various embodiments, the integrated circuit arrangement 300 may include one or more integrated circuits 302. In various embodiments, the integrated circuit arrangement 300 may include one or more logic circuits and/or one or more memory circuits. In various embodiments, the integrated circuit arrangement 300 may include one or more individual (i.e. e.g. individually packaged) semiconductor components such as e.g. one or more individual (i.e. e.g. individually packaged) power semiconductor components. In various embodiments, the integrated circuit arrangement 300 may include one or more field effect transistors (FETs) (e.g. metal oxide semiconductor (MOS) FETs, e.g. power MOSFETs) and/or one or more bipolar transistors. Furthermore, in various embodiments, the integrated circuit arrangement 300 may include one or more thyristors and/or one or more insulated-gate bipolar transistors (IGBTs). In various embodiments, the integrated circuit arrangement 300 may include one or more integrated circuits being stacked one above the other, wherein the integrated circuits may already been partially of completely packaged.

One implementation of an integrated circuit arrangement 300 as shown in FIG. 3 may include an integrated circuit, e.g. an IGBT. The integrated circuit arrangement 300 may include a substrate 302, e.g. made of silicon, and four terminals (as a respective implementation of an integrated circuit contact) (it is to be noted that other integrated circuit arrangements 300 may have a different number of terminals, e.g. one, two, three, or more than four, even tens or hundreds of terminals, depending on the application). The integrated circuit arrangement 300 as shown in FIG. 3 has four terminals, namely e.g. an emitter terminal 304, a base terminal 306, a gate terminal 308, as well as a collector terminal 310. In various embodiments, the collector terminal 310 is a back side terminal of the integrated circuit arrangement 300. Furthermore, the IGBT includes all as such conventional semiconductor regions in the substrate 302, suitably doped, to provide the functionality of an IGBT. However, a detailed description of those conventional structures and layers in the substrate 302 will be omitted here for reasons of clarity. Furthermore, as a back side metallization, of the integrated circuit arrangement 300, a metallization layer stack 312 may be provided and (mechanically and electrically) coupled to the collector terminal 310. In various embodiments, the metallization layer stack 312 may be a back side metallization layer stack 312. In various embodiments, the metallization layer stack 312 may be implemented in any form as e.g. in accordance with any embodiment of a layer stack 100, 200, as shown in FIG. 1 or FIG. 2. In other words, the metallization layer stack 312 may be implemented as layer stack 100, alternatively as layer stack 200.

In various embodiments, an implementation of various embodiments may be provided, in which the substrate 102 includes or consists of silicon, the first metal 104 includes or consists of Al or Ti or (Al and Ti), the second metal 106 includes or consists of WTi, the adhesion conditioning layer 202 includes or consists of NiV, the soldering (passivation) layer 108 includes or consists of Ag, and the solder material 302 includes or consists of AuSn. In various embodiments, the first metal 104 may include a double layer structure including a first layer of e.g. Al and a second layer of e.g. Ti.

In various embodiments, the material of the second metal 106 (e.g. WTi) is very temperature-resistant, has a low diffusibility and thus serves as a solder stop for a wide range of solder materials. By way of example, in case the conventional Ti layer is replaced by the second metal layer 106 (e.g. WTi), the generation of TiₓSn_{y}[Me_{z}] phases is avoided. A delamination at the Ti interface is therefore no longer possible. The deposition of the second metal 106 (e.g. WTi) makes only little demands to the deposition process and there are no additional constraints to the subsequent processes. By way of example, any as such conventional backside metallization (BSM) magnetron physical vapor deposition (PVD) assembly is capable to deposit the second metal 106 (e.g. WTi), e.g. by replacing the (conventional) Ti target with a WTi target (in general with a target of the material(s) of the second metal 106), e.g. having 10 weight percent Ti, to thereby produce the metallization layer stack, e.g. the BSM stack in accordance with various embodiments.

In various embodiments, the second metal 106 (e.g. WTi) may replace the (conventional) Ti layer or is deposited above the Ti layer to provide the solder stop, e.g. after the material of the adhesion conditioning layer 202 has been dissolved. After the solder is stopped at the second metal 106 (e.g. WTi), a thermal equilibrium has been established in the layer/solder stack (which may also be referred to as a system). The formation of TiₓSn_{y}Me_{z} and a possible delamination may be avoided. The adhesion between the second metal 106 (e.g. WTi) and the adjacent layers, e.g. including NiV, is good.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A layer stack, comprising:
a carrier;
an integrated circuit contact provided on the carrier;
a back side terminal provided on or in the carrier on a side thereof opposite to the integrated circuit contact;
a first metal disposed over the carrier and over the back side terminal, and providing an electrical contact to the back side terminal;
a second metal disposed over the first metal; and
a solder material disposed over the second metal, or a material disposed over the second metal for providing contact to a solder that is supplied by an external source;
wherein the second metal has a melting temperature of at least 1800° C. and is an adhesive layer to the solder material and is substantially indissolvable in the solder material during a soldering process.

2. The layer stack of claim 1,
wherein the first metal comprises a metal selected from a group of metals consisting of aluminum; titanium; and an alloy of the mentioned metals.

3. The layer stack of claim 1,
wherein the second metal comprises a metal selected from a group of metals consisting of: tungsten (W), tantalum (Ta), molybdenum (Mo), chromium (Cr), and vanadium (V).

4. The layer stack of claim 1,
wherein the second metal comprises a plurality of metal components;
wherein a first metal component of the plurality of metal components comprises a metal selected from a group of metals consisting of: tungsten; tantalum; molybdenum; chromium; niobium; and hafnium; and
wherein a second metal component of the plurality of metal components comprises a metal selected from a group of metals consisting of: zirconium and vanadium.

5. The layer stack of claim 1, further comprising:
AuSn as a soldering layer disposed over the second metal, wherein the AuSn is a eutectic phase during a soldering process.

6. The layer stack of claim 1, further comprising:
a soldering layer disposed over the second metal, wherein the soldering layer is a peritecticum with the solder material during a soldering process.

7. The layer stack of claim 6,
wherein the soldering layer comprises a material selected from a group consisting of: silver and gold-tin.

8. The layer stack of claim 1, further comprising:
an adhesion conditioning layer disposed over the second metal.

9. The layer stack of claim 1, further comprising:
a protection layer disposed over the second metal.
